(19) United States
(12) Patent Application Publication
(10) Pub. No.: US 2021/0164100 A1
(43) Pub. Date: Jun. 3, 2021

(54) APPARATUS AND METHOD

(71) Applicant: BENEQ OY, Espoo (FI)

(72) Inventor: Pekka SOININEN, Espoo (FI)

(21) Appl. No.: 17/047,744

(22) PCT Filed: Apr. 15, 2019
(86) PCT No.: PCT/FI2019/050300

§ 371 Date: Oct. 15, 2020

(30) Foreign Application Priority Data
Apr. 16, 2018 (FI) 20185358

(51) Int. Cl. C23C 16/455; C23C 16/44

(52) U.S. Cl. CPC C23C 16/45551; C23C 16/45593; C23C 16/4412

(57) ABSTRACT

A method and an apparatus including a nozzle head having an output face and including at least one precursor nozzle including a supply channel and at least one discharge nozzle including a discharge channel. The apparatus further including a supply line in a fluid communication with the supply channel of the precursor nozzle; and a discharge line in a fluid communication with the discharge channel of the discharge nozzle. The discharge line is connected to the supply line for circulating precursor in the nozzle head by returning at least part of the discharge flow from the output face of the nozzle head via the discharge channel of the discharge nozzle to the supply channel of the precursor nozzle.

### FIELD OF THE INVENTION

The present invention relates to an apparatus for subjecting a surface of a substrate to alternate surface reactions of at least two precursors according to the principles of atomic layer deposition, and more particularly to an apparatus as defined in the preamble of the independent claim 1.

The present invention further relates to a method for circulating precursor in an apparatus for subjecting a surface of a substrate to alternate surface reactions of at least two precursors according to the principles of atomic layer deposition, and more particularly to a method as defined in the preamble of the independent claim 8.

### BACKGROUND OF THE INVENTION

In prior art spatial ALD-apparatuses and methods for coating a surface of a substrate with an ALD method in which the precursor supplied from the precursor nozzle to the surface of the substrate has to have a sufficient level of precursor partial pressure in order to provide a high quality coating on the surface of the substrate. Determining this sufficient level of partial pressure of precursors before or during the coating process is very difficult. This causes a problem: In order to make sure that a sufficient level of precursor partial pressure is provided to the ALD coating process, the amount of precursor supplied through the precursor nozzle has to be more than the surface of the substrate can adsorb. This naturally leads to precursor losses, filter blockages and ultimately breakdowns of vacuum pumps as excess precursors are purged out of the process and then form so-called residual growth into the parts downstream of the coating section of the ALD tool. Residual growth into the vacuum pumps is especially harmful as it can break down the valuable pump.

### BRIEF DESCRIPTION OF THE INVENTION

An object of the present invention is to provide an apparatus and a method for circulating at least one precursor in the apparatus such that at least part of the precursor supplied through a nozzle head is circulated back to the precursor supply to the nozzle head.

The objects of the invention are achieved by an apparatus and a method which are characterized by what is stated in the independent claims. The preferred embodiments of the invention are disclosed in the dependent claims.

The invention is based on the idea of circulating at least part of the precursor supplied from the nozzle head toward the surface of the substrate back to a precursor nozzle through a discharge nozzle. The invention relates to an apparatus for subjecting a surface of a substrate to alternate surface reactions of at least two precursors according to principles of atomic layer deposition.

The apparatus according to the invention comprises a nozzle head having an output face via which the at least one precursor is supplied towards the surface of the substrate. The nozzle head comprises at least one precursor nozzle provided on the output face of the nozzle head and comprising a supply channel for supplying precursor towards the surface of the substrate via the output face; and at least one discharge nozzle provided on the output face of the nozzle head and comprising a discharge channel for discharging precursor from the output face. The apparatus further comprises a supply line for supplying precursor from a precursor source to the at least one precursor nozzle. The supply line is connected to the precursor nozzle and being in a fluid communication with the supply channel of the precursor nozzle; and a discharge line for discharging precursor and generating a discharge flow from the output face. The discharge line is connected to the discharge nozzle and being in a fluid communication with the discharge channel of the discharge nozzle.

The supply channel is provided in the precursor nozzle preferably such that it comprises an opening in the output face of the nozzle head. The supply line and the supply channel are in fluid communication and in some embodiments of the invention the supply line may even be provided as the supply channel meaning that the supply line and the supply channel are the same. In some embodiments of the invention the supply line is provided at least partly outside of the nozzle head and extending between a precursor source and the nozzle head or between the precursor source and the precursor nozzle or between the precursor source and the supply channel in the precursor nozzle.

The discharge channel in the discharge nozzle is preferably provided in the nozzle head such that the discharge channel comprises an opening in the output face of the nozzle head. The discharge line and the discharge channel are in fluid communication and in some embodiments of the invention the discharge line and the discharge channel may even be provided as one discharge channel meaning that the discharge line and the discharge channel are the same. In some embodiments of the invention the discharge line is provided at least partly outside the nozzle head and extending between the discharge nozzle in the nozzle head and the supply line or between the discharge channel in the discharge nozzle and the supply line. In other words, the discharge line is connected to the supply line for circulating precursor in the nozzle head by returning at least part of the discharge flow from the output face of the nozzle head via the discharge channel of the discharge nozzle to the supply channel of the precursor nozzle as a circulation flow. The discharge flow is a flow that is generated from an excess precursor that is left over when the surface of the substrate is applied with the precursor supplied from the precursor nozzle and which is discharged from the output face of the nozzle head to the discharge channel in the discharge nozzle and the circulation flow is the part of the discharge flow that is returned from the discharge line to the supply line to be supplied through the supply channel of the precursor nozzle again.

In an embodiment of the invention the nozzle head comprises at least two precursor nozzles provided on the output face of the nozzle head such that at least one first precursor nozzle is arranged to supply a first precursor and at least one second precursor nozzle is arranged to supply a second precursor. The apparatus then comprises a first supply line for supplying the first precursor from a first precursor source to the at least one first precursor nozzle and a second supply line for supplying the second precursor from a second precursor source to the at least one second precursor nozzle. The first supply line is connected to the first precursor nozzle and being in a fluid communication with the supply channel of the first precursor nozzle and the second supply line is connected to the second precursor nozzle and being in a fluid communication with the supply channel of the second precursor nozzle. The apparatus further comprises a first discharge line for discharging the first precursor and generating a discharge flow from the output face and a second discharge line for discharging the second precursor and generating a discharge flow from the output face. The first discharge line is connected to the first discharge nozzle and being in a fluid communication with the discharge channel of the first discharge nozzle and the second discharge line is connected to the second discharge nozzle and being in a fluid communication with the discharge channel of the second discharge nozzle. The first discharge line is connected to the first supply line for circulating the first precursor in the nozzle head by returning at least part of the discharge flow of the first precursor from the output face of the nozzle head via the discharge channel of the first discharge nozzle to the first supply channel of the first precursor nozzle as a circulation flow, and the second discharge line is connected to the second supply line for circulating the second precursor in the nozzle head by returning at least part of the discharge flow of the second precursor from the output face of the nozzle head via the discharge channel of the second discharge nozzle to the supply channel of the second precursor nozzle as a circulation flow. In other words, this embodiment of the invention comprises at least two precursor circulations in the apparatus such that the first precursor is circulated in a first precursor loop and the second precursor is circulated in a second precursor loop. Said first precursor loop comprises the first supply line, the supply channel of the first precursor nozzle, the discharge channel of the first discharge nozzle and the first discharge line and said second precursor loop comprises the second supply line, the supply channel of the second precursor nozzle, the discharge channel of the second discharge nozzle and the second discharge line.

In another embodiment of the invention the nozzle head comprises at least two discharge nozzles and at least one precursor nozzle such that one precursor nozzle is provided between two discharge nozzles. The apparatus then comprises at least two discharge lines for discharging precursor and generating a discharge flow from the output face. The at least two discharge lines being connected to the discharge nozzles provided on opposite sides of the precursor nozzle and being in a fluid communication with the discharge channels of the discharge nozzles. The discharge lines are connected to the supply line for circulating precursor in the nozzle head by returning at least part of the discharge flow from the output face of the nozzle head via the discharge channels of the discharge nozzles to the supply channel of the precursor nozzle as circulation flows. In other words, the apparatus comprises at least two loops for circulating at least part of the discharge flow from the output face of the nozzle head through at least two discharge lines to the same supply line as two separate circulation flows.

In an embodiment of the invention the discharge line comprises at least one of the following: a pump for circulating a discharge flow and/or a circulation flow; a first filter for filtering the discharge flow or the circulation flow; a first mass flow controller for regulating the circulation flow to the supply line or for regulating the ratio of the circulation flow divided from the discharge flow to the supply line; or a coupling with an exhaust ventilation for connecting the discharge line to the exhaust ventilation.

In another embodiment of the invention the discharge line comprises a first mass flow controller and a filter provided upstream side of the mass flow controller. In another embodiment of the invention the discharge line comprises a first mass flow controller and a pump provided upstream side of the mass flow controller. In another embodiment of the invention the discharge line comprises a first mass flow controller, a pump and a first filter such that said pump is provided upstream side of the mass flow controller and said first filter is provided upstream side of the pump. In another embodiment of the invention the discharge line comprises a first mass flow controller, a pump, a first filter and a second filter such that said second filter is provided upstream side of the mass flow controller, said pump is provided upstream side of the second filter and said first filter is provided upstream side of the pump.

In an embodiment of the invention the supply line comprises a second mass flow controller for regulating precursor flow from the precursor source. The second mass flow controller is provided in the supply line between the precursor source and the connection of the discharge line to the supply line.

In an embodiment of the invention the discharge line is connected to the supply line with a first coupling and to an exhaust ventilation with a second coupling, and the first mass flow controller is provided in the discharge line between the first coupling and the second coupling. In other words, the first mass flow controller is provided in the discharge line to regulate the circulation flow which is the part of the discharge flow that is separated in the second coupling in which part of the discharge flow is directed to the exhaust ventilation and part of the discharge flow is circulated back to the precursor nozzle as a circulation flow.

The invention further relates to a method for circulating precursor in an apparatus for subjecting a surface of a substrate to alternate surface reactions of at least two precursors according to the principles of atomic layer deposition in which the apparatus comprises a nozzle head having an output face and at least one precursor nozzle and at least one discharge nozzle provided on the output face. The method according to the invention comprises the steps of supplying precursor from the precursor nozzle via the output face toward the surface of the substrate as a precursor flow; discharging precursor from the output face through the discharge nozzle as a discharge flow; and returning at least part of the discharge flow from the discharge nozzle to the precursor nozzle as a circulation flow. In other words, the precursor supplied from the precursor nozzle toward the surface of the substrate is the precursor flow for coating the surface of the substrate and an excess precursor that is left over and discharged from the output face to the discharge nozzle is the discharge flow. The part of the discharge flow that is returned back to the precursor nozzle is the circulation flow. The method in other words comprises steps of supplying a precursor flow from a precursor nozzle, discharging a discharge flow via a discharge nozzle and returning a circulation flow from the discharge nozzle back to the precursor nozzle.

The discharge flow comprises the excess precursor gas that is left over when the surface of the substrate is subjected to surface reactions and it may also comprise purge gas which is used as a barrier gas or for flushing. The circulation flow comprises precursor gas which is filtered and/or otherwise purified and/or from which part of is directed to exhaust ventilation.

The apparatus comprises a supply line extending from a precursor source to a precursor channel in the precursor nozzle and a discharge line extending from the discharge nozzle to the supply line and the method further comprises the step of circulating the at least part of the discharge flow through the discharge line to the supply line as the circulation flow.

In an embodiment of the invention the method further comprises the step of dividing the discharge flow to the circulation flow and an exhaust flow. Said circulation flow is returning to the supply line as part of the precursor flow and the exhaust flow is directed to the exhaust ventilation. In other words, the method further comprises the step of leading the circulation flow to the supply line as part of the precursor flow. The method further comprises the step of leading part of the discharge flow as an exhaust flow to the exhaust ventilation.

In an embodiment of the invention the apparatus further comprises a first mass flow controller provided in the discharge line and the method further comprises the step of regulating the circulation flow to the supply line by the first mass flow controller; or regulating the ratio of the circulation flow divided from the discharge flow to the supply line by the first mass flow controller.

In an embodiment of the invention the apparatus further comprises a first filter provided in the discharge line and the method further comprises the step of filtering the circulation flow upstream of the supply line.

In an embodiment of the invention the apparatus further comprises a second mass flow controller provided in the supply line and the method further comprises the step of regulating the precursor flow supplied from the precursor source with the second mass flow controller.

In an embodiment of the invention the nozzle head comprises at least two precursor nozzles and at least two discharge nozzles provided on the output face of the nozzle head and the method comprises the steps of supplying a first precursor from a first precursor nozzle via the output face toward the surface of the substrate as a first precursor flow; supplying a second precursor from a second precursor nozzle via the output face toward the surface of the substrate as a second precursor flow; discharging the first precursor from the output face through a first discharge nozzle as a first discharge flow; discharging the second precursor from the output face through a second discharge nozzle as a second discharge flow; returning at least part of the first discharge flow through the first discharge nozzle to the first precursor nozzle as a first circulation flow; and returning at least part of the second discharge flow through the second discharge nozzle to the second precursor nozzle as a second circulation flow.

In the apparatus according to the invention, the apparatus comprises a nozzle head having an output face via which the at least one precursor is supplied towards the surface of the substrate, said nozzle head comprising at least one precursor nozzle provided on the output face of the nozzle head and comprising a supply channel for supplying precursor towards the surface of the substrate via the output face, and at least one discharge nozzle provided on the output face of the nozzle head and comprising a discharge channel for discharging precursor from the output face. The apparatus further comprises a supply line for supplying precursor from a precursor source to the at least one precursor nozzle and a discharge line for discharging precursor and generating a discharge flow from the output face. The supply line is connected to the precursor nozzle and is in a fluid communication with the supply channel of the precursor nozzle and the discharge line is connected to the discharge nozzle and is in a fluid communication with the discharge channel of the discharge nozzle. The supply line is extending from the precursor source to the precursor channel in the precursor nozzle and the discharge line is extending from the discharge nozzle to the supply line such that the discharge line is connected to the supply line for circulating precursor in the nozzle head by returning at least part of the discharge flow from the output face of the nozzle head via the discharge channel of the discharge nozzle to the supply channel of the precursor nozzle. In other words, the discharge line and the supply line are connected together for circulating the precursor in the nozzle head. In still other words, the supply line is arranged to extend from the precursor source to the precursor channel in the precursor nozzle in the nozzle head and the discharge line is connected to the supply line between the precursor source and the nozzle head. Therefore the connection between the supply line and the discharge line is in the apparatus between the precursor source and the nozzle head such that the discharge line is not extending to the precursor source nor to the nozzle head but to the supply line extending between the precursor source and the nozzle head.

In the method according to the invention, the method comprises the steps of supplying precursor from a precursor nozzle in a nozzle head via an output face toward a surface of a substrate as a precursor flow, discharging precursor from the output face through a discharge nozzle in the nozzle head as a discharge flow; and returning at least part of the discharge flow from the discharge nozzle to the precursor nozzle as a circulation flow by circulating the at least part of the discharge flow through a discharge line to a supply line as the circulation flow. The step of returning at least part of the discharge flow from the discharge nozzle to the precursor nozzle is provided through a discharge line extending from the discharge nozzle to the supply line which the supply line is extending from a precursor source to a precursor channel in the precursor nozzle in the nozzle head. In other words, the discharge line is connected to the supply line extending between the precursor source and the nozzle head.

The method described above can be utilized with the apparatus as described above.

An advantage of the invention is that precursor supplied from a precursor source to the apparatus is more effectively used because it can be partly reused again. The loss of precursor can be reduced when the excess precursor is returned back to the precursor nozzle by discharging the precursor via the discharge nozzle to the precursor nozzle. The excess precursor is the part of the precursor which is left over when the surface of the substrate is coated with precursor and the amount of precursor supplied from the precursor nozzle toward the surface of the substrate is more than needed for the surface reactions.

### BRIEF DESCRIPTION OF THE DRAWINGS

The invention is described in detail by means of specific embodiments with reference to the enclosed drawings, in which

FIG. 1 shows a flow diagram of the method according to the invention;

FIG. 2 shows one embodiment of the method according to the invention;

FIG. 3 shows another embodiment of the method according to the invention;

FIG. 4 shows the apparatus according to the invention;

FIG. 5 shows one embodiment of the apparatus according to the invention;

FIG. 6 shows another embodiment of the apparatus and the method according to the invention;

FIG. 7 shows still another embodiment of the apparatus according to the invention;

FIG. 8 shows still another embodiment of the apparatus according to the invention;

FIG. 9 shows yet another embodiment of the apparatus according to the invention; and

FIG. 10 shows still another embodiment of the apparatus according to the invention.

### DETAILED DESCRIPTION OF THE INVENTION

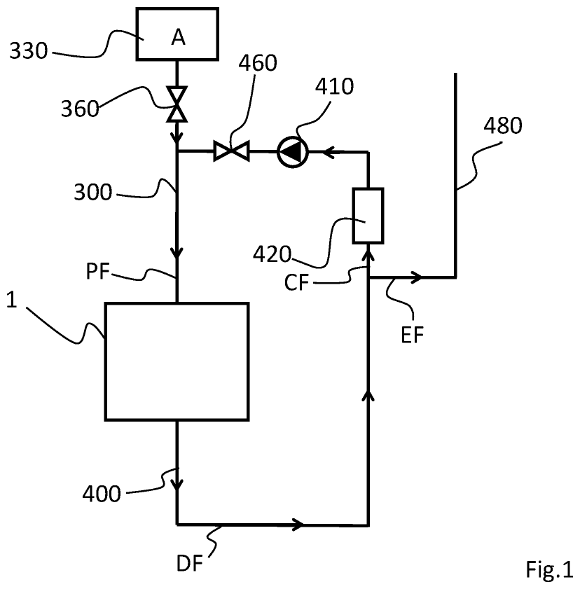

FIG. 1 shows an apparatus and a method for circulating precursor according to the invention in which precursor A is supplied from a precursor source 330 to the nozzle head 1 through a supply line 300 as a precursor flow PF. The nozzle head 1 comprises at least one precursor nozzle and at least one discharge nozzle (not shown in the figure but are contained in the nozzle head 1). The precursor A supplied from the precursor source 330 is supplied toward a surface of a substrate via an output face of the nozzle head 1 as a precursor flow PF. In other words, the supply line 300 supplies the precursor flow PF. The precursor A is discharged from the output face through the discharge nozzle of the nozzle head 1 as a discharge flow DF. The discharge flow DF is in FIG. 1 lead through a discharge line 400 toward the supply line 300. The discharge flow DF is divided into a circulation flow CF and an exhaust flow EF. The exhaust flow EF is lead to an exhaust ventilation 480 and the circulation flow CF is lead to the supply line 300. In the embodiment shown in FIG. 1 the discharge line 400 comprises a filter 420 for filtering the circulation flow CF, a pump 410 for pumping the circulation flow CF and a first mass flow controller 460 for regulating the circulation flow CF. The supply line 300 also comprises a mass flow controller which is referred as a second mass flow controller 360 and which regulates the precursor A supplied from the precursor source 330 through the supply line 330.

The mass flow controllers disclosed in this application are for regulating the precursor supply from the precursor source, the circulation flow returning to the supply line or the ratio of the circulation flow divided from the discharge flow. The mass flow controllers measure and control the precursor flow from the precursor source and the circulation flow in the discharge line 400. The first mass flow controller 460 provided in the discharge line 400 controls the amount of precursor flowing in the loop formed of the supply line 300 and the discharge line 400 connected to the supply line 300. When the amount precursor provided in the loop decreases more precursor is supplied from the precursor source 330 which the supply is regulated by the second mass flow controller 360. The discharge flow generated from the output face 2 of the nozzle head 1 may comprise purge gas meaning that the precursor content in the discharge flow will reduce and therefore part of the discharge flow may be exhausted through exhaust ventilation 480 and the amount exhaust through the exhaust ventilation will be replaced by new precursor from the precursor source regulated by the second mass flow controller 360.

As shown in FIG. 1 the precursor supplied from the precursor source 330 to the supply line 300 is circulated in a loop formed of the supply line 300 and the discharge line 400 such that the discharge line is connected to the supply line 300 extending between the precursor source 330 and the nozzle head 1. In other words, the discharge line 400 is extending between the discharge nozzle of the nozzle head and the supply line 300, and the supply line 300 is extending between the precursor source 330 and the precursor nozzle of the nozzle head 1. In still other words, the supply line 300 is extending between the precursor source 330 and the nozzle head 1, and the discharge line 400 is extending between the nozzle head 1 and the supply line 300 such that a loop is formed. The loop is formed from the nozzle head 1, the discharge line 400 and the supply line 300 such that the supply line 300 is connected to the nozzle head 1, the nozzle head 1 and the discharge line 400 are connected together and the discharge line 400 is connected to the supply line 300.

The FIG. 1 shows the nozzle head 1 which comprises at least one precursor nozzle and at least one discharge nozzle. The nozzle head 1 having an output face via which the at least one precursor is supplied towards the surface of the substrate. The at least one precursor nozzle is provided on the output face of the nozzle head and comprises a supply channel for supplying precursor towards the surface of the substrate via the output face. The at least one discharge nozzle is also provided on the output face of the nozzle head 1 and comprises a discharge channel for discharging precursor from the output face. The discharge line 400 is connected to the discharge channel in the discharge nozzle of the nozzle head 1 and the supply line is connected to the supply channel in the supply nozzle of the nozzle head 1.

FIG. 1 shows the method according to the invention in which the steps of supplying precursor A from the precursor nozzle of the nozzle head 1 via the output face toward the surface of the substrate as a precursor flow PF; discharging precursor A from the output face through the discharge nozzle as a discharge flow DF; and returning at least part of the discharge flow DF from the discharge nozzle to the precursor nozzle as a circulation flow CF are performed.

The circulation flow CF is either a part of the discharge flow DF that is not lead to an exhaust ventilation 480 as an exhaust flow EF, or the discharge flow DF that is filtered with a filter 420 or the part of the discharge flow that is not lead to an exhaust ventilation 480 as an exhaust flow EF and that is filtered with a filter 420. The discharge line 400 may comprise a filter before the coupling to the exhaust ventilation 480 and/or after the coupling to the exhaust ventilation 480 meaning that the method may comprise the steps of filtering the discharge flow DF and/or filtering the circulation flow CF.

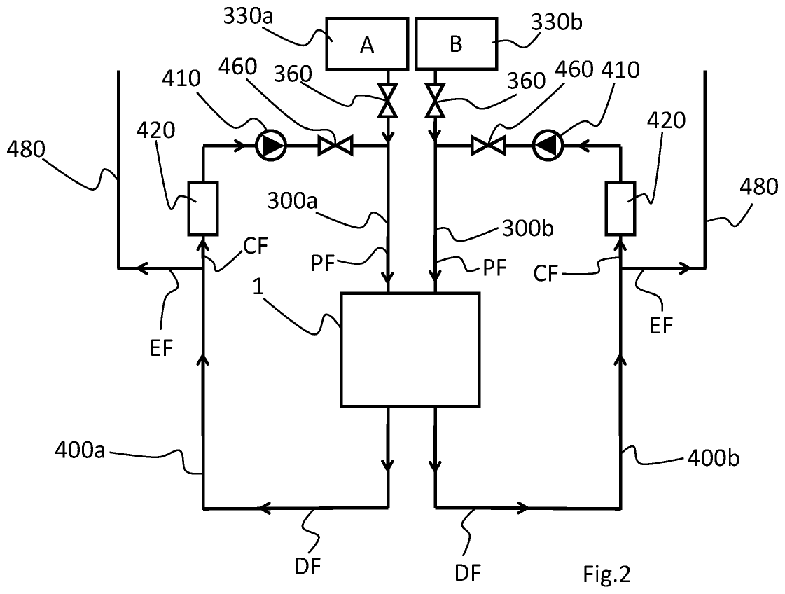

FIG. 2 shows an embodiment of the invention in which two precursors A and B are supplied from precursor sources 330a, 330b and supplied toward the surface of the substrate through the same nozzle head 1 but through different precursor nozzles and the precursors A and B are circulated in separate loops. The nozzle head 1 comprises (although not shown in the figure) at least two precursor nozzles provided on the output face of the nozzle head such that at least one first precursor nozzle is arranged to supply a first precursor A and at least one second precursor nozzle is arranged to supply a second precursor B. The apparatus comprises a first supply line 300a for supplying the first precursor A from a first precursor source 330a to the at least one first precursor nozzle. The first supply line 300a is connected to the first precursor nozzle and is in a fluid communication with the supply channel of the first precursor nozzle. The second supply line 300b for supplying the second precursor B from a second precursor source 330b to the at least one second precursor nozzle is similarly connected to the second precursor nozzle and is in a fluid communication with the supply channel of the second precursor nozzle. The first precursor supplied from the first precursor source 330a to the nozzle head 1 is for the sake of clarity called the first precursor flow PF1 and the second precursor supplied from the second precursor source 330b to the nozzle head 1 is called the second precursor flow PF2. A first discharge line 400a for discharging the first precursor A and generating a first discharge flow DF1 from the output face is connected to the first discharge nozzle and is in a fluid communication with the discharge channel of the first discharge nozzle and a second discharge line 400b for discharging the second precursor B and generating a second discharge flow DF2 from the output face 2 is connected to the second discharge nozzle and is in a fluid communication with the discharge channel of the second discharge nozzle. The precursor flows and the discharge flows, either being the first or second, may be referred in this application commonly as precursor flows PF and discharge flows DF, the context where the flows are referred defines whether they are the first or second flows. The first discharge line 400a is connected to the first supply line 300a for circulating the first precursor A in the nozzle head 1 by returning at least part of the discharge flow DF from the output face of the nozzle head 1 via the discharge channel of the first discharge nozzle to the first supply channel of the first precursor nozzle, and the second discharge line 400b is connected to the second supply line 300b for circulating the second precursor B in the nozzle head 1 by returning at least part of the discharge flow DF from the output face of the nozzle head 1 via the discharge channel of the second discharge nozzle to the supply channel of the second precursor nozzle. In other words, as the FIG. 1 show a loop for circulating one precursor FIG. 2 shows two loops for circulating two different precursors. Otherwise, the filters 420, the pumps 410 and the first and second mass flow controllers 460, 360 are similar as described in connection with FIG. 1.

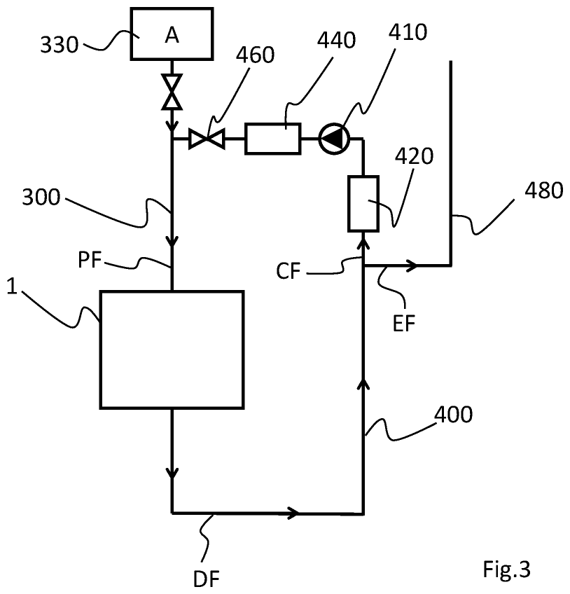

FIG. 3 shows an embodiment of the invention in which there are two filters 420, 440 provided in the discharge line 400. The discharge line 400 comprises in this embodiment a first mass flow controller 460, a pump 410, a first filter 420 and a second filter 440. The second filter 440 is provided upstream side of the mass flow controller 460, the pump 410 is provided upstream side of the second filter 440 and said first filter 420 is provided upstream side of the pump 410. The first filter 420 is provided in the discharge line 400 downstream side of the coupling to the exhaust ventilation 480. Alternatively, the first filter 420 may be provided in the discharge line 400 upstream side of the coupling to the exhaust ventilation 480 or alternatively the discharge channel may comprise two first filters 420 provided in the discharge line 400 upstream side and downstream side of the coupling to the exhaust ventilation 480. The upstream side being the earlier point in relation to the referred device in the direction of the flow and the downstream side being the later point in relation to the referred device in the direction of the flow.

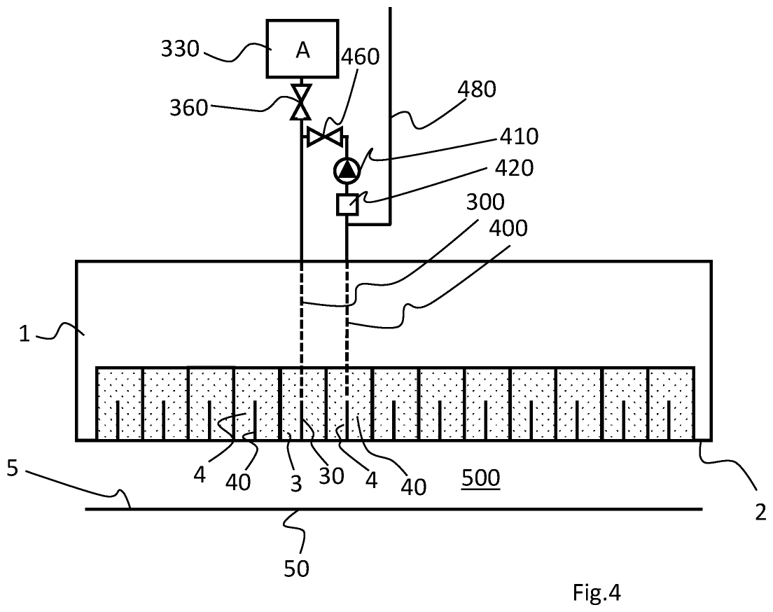

FIG. 4 shows the apparatus according to the invention in which a nozzle head 1 is provided with at least one precursor nozzle 3 provided on the output face 2 of the nozzle head 1 and comprising a supply channel 30 for supplying precursor towards the surface 5 of the substrate 50 via the output face 2 and at least one discharge nozzle 4 provided on the output face 2 of the nozzle head 1 and comprising a discharge channel 40 for discharging precursor from the output face 2. A supply line 300 for supplying precursor from a precursor source 330 to the at least one precursor nozzle 3 is connected to the precursor nozzle 3 and is in a fluid communication with the supply channel 30 of the precursor nozzle 3. A discharge line 400 for discharging precursor and generating a discharge flow from the output face 2 is connected to the discharge nozzle 4 and is in a fluid communication with the discharge channel 40 of the discharge nozzle 4. The discharge line 400 comprises a first filter 420, a pump 410 and a first mass flow controller 460 and a coupling to the exhaust ventilation 480. The supply line comprises a second mass flow controller and a coupling between the supply line 300 and the discharge line 400. The second mass flow controller 360 is provided between the precursor source 330 and the coupling between the supply line 300 and the discharge line 400. FIG. 4 shows also a reaction space 500 provided between the surface 5 of the substrate 50 and the output face 2 of the nozzle head 1. The reaction space 500 is where the excess precursor gas that is supplied from the precursor nozzle 3 but which left over when the surface of the substrate has been coated.

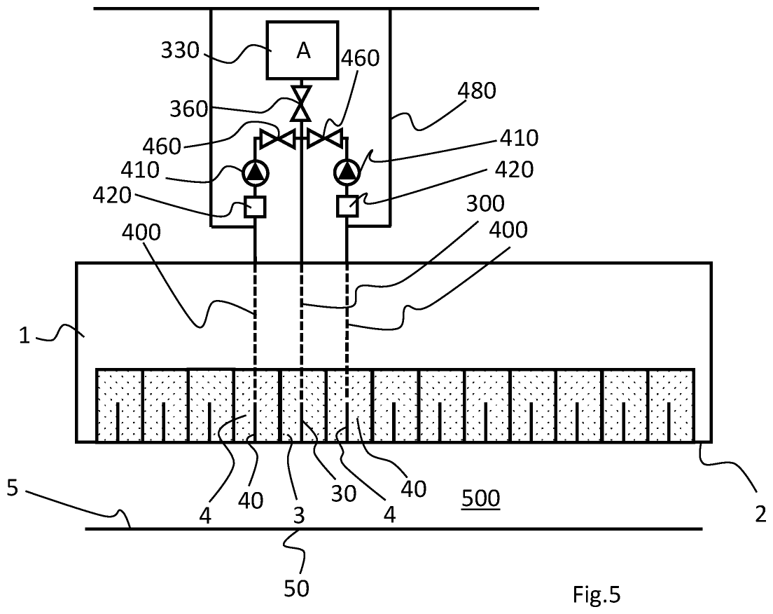

FIG. 5 shows an embodiment of the invention in which the nozzle head 1 comprises at least two discharge nozzles 4 and at least one precursor nozzle 3 such that one precursor nozzle 3 is provided between two discharge nozzles 4. The apparatus then comprises at least two discharge lines 400 for discharging precursor and generating a discharge flow from the output face 2 connected to the discharge nozzles 4 which are provided on opposite sides of the precursor nozzle 3 and which are in a fluid communication with the discharge channels 40 of the discharge nozzles 4. The discharge lines 400 are connected to the supply line 300 for circulating precursor in the nozzle head 1 by returning at least part of the discharge flow from the output face 2 of the nozzle head 1 via the discharge channels 40 of the discharge nozzles 4 to the supply channel 30 of the precursor nozzle 3. In other words, there are two loops for circulating the same precursor such that there are two discharge lines 400 to return at least part of the discharge flow to the supply line 300.

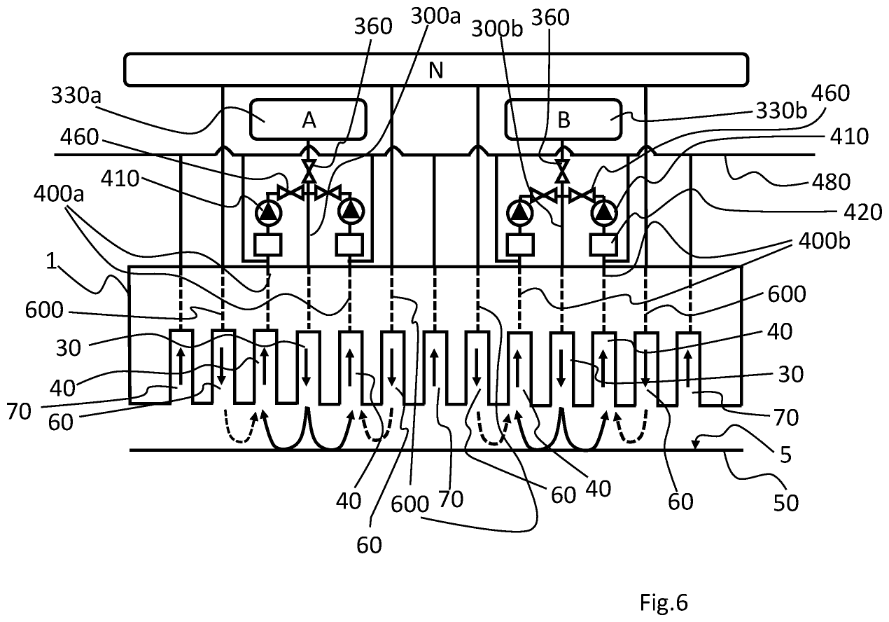

FIG. 6 shows an embodiment in which there are two different precursors A and B and the nozzle head 1 comprises at least two discharge nozzles 4 and at least one precursor nozzle 3 for the first precursor A such that one precursor nozzle 3 is provided between two discharge nozzles 4; and at least two discharge nozzles 4 and at least one precursor nozzle 3 for the second precursor B such that one precursor nozzle 3 is provided between two discharge nozzles 4. The apparatus comprises at least two discharge lines 400a for discharging the first precursor A and generating a discharge flow from the output face 2. The at least two discharge lines 400a are connected to the discharge nozzles 4 provided on opposite sides of the precursor nozzle 3 and are in a fluid communication with the discharge channels 40 of the discharge nozzles 4 and at least two discharge lines 400b for discharging the second precursor B and generating a discharge flow from the output face 2. The at least two discharge lines 400ab are connected to the discharge nozzles 4 provided on opposite sides of the precursor nozzle 3 and are in a fluid communication with the discharge channels 40 of the discharge nozzles 4. The discharge lines 400a for the first precursor A are connected to the supply line 300a for circulating precursor in the nozzle head 1 by returning at least part of the discharge flow from the output face 2 of the nozzle head 1 via the discharge channels 40 of the discharge nozzles 4 to the supply channel 30 of the precursor nozzle 3 and similarly the discharge lines 400b for the second precursor B are connected to the supply line 300b for circulating precursor in the nozzle head 1 by returning at least part of the discharge flow from the output face 2 of the nozzle head 1 via the discharge channels 40 of the discharge nozzles 4 to the supply channel 30 of the precursor nozzle 3. The discharge lines 400a and 400b comprise filters 420, pumps 410, first mass flow controllers 460 and exhaust ventilations 480 as already explained in connection with previous figures and the supply lines 300a, 300b comprise a second mass flow controller 360 as described in context with previous figures.

FIG. 6 also shows a purge gas source N providing purge gas through a purge gas line 600 to a purge gas nozzle provided on the output face 2 of the nozzle head 1 and comprising a purge channel 60 for supplying purge gas towards the surface 5 of the substrate 50 via the output face 2. The nozzle head 1 shown in FIG. 6 comprises multiple purge gas lines 600 connected to purge gas channels 60. FIG. 6 also shows additional discharge channels 70 which are connected only to an exhaust ventilation 480. These additional discharge channels 70 are provided to discharge purge gas.

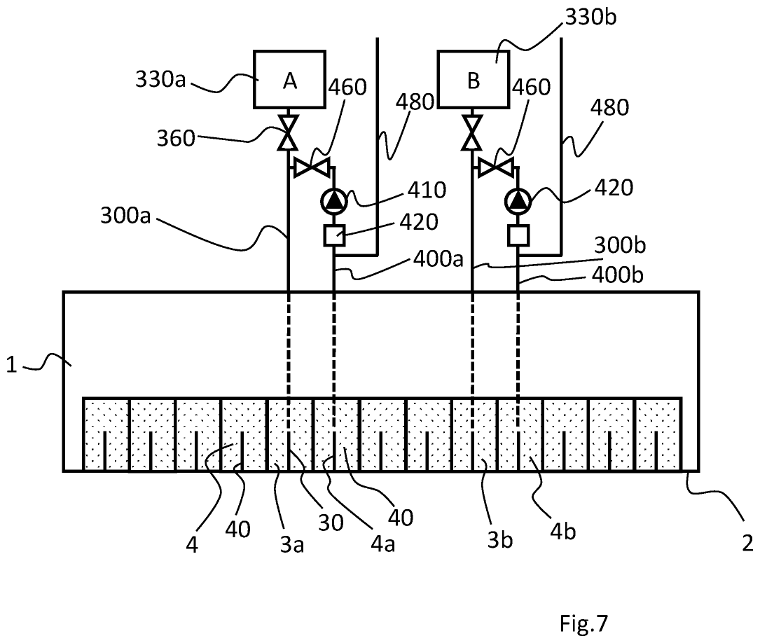

FIG. 7 shows an embodiment of the invention which comprises a nozzle head 1 having at least two precursor nozzles 3 provided on the output face 2 of the nozzle head 1 such that at least one first precursor nozzle 3a is arranged to supply a first precursor A and at least one second precursor nozzle 3b is arranged to supply a second precursor B. The apparatus comprises a first supply line 300a for supplying the first precursor A from a first precursor source 330a to the at least one first precursor nozzle 3a and connected to the first precursor nozzle 3a such that the first supply line 300a is in a fluid communication with the supply channel 30 of the first precursor nozzle 3a. The apparatus comprises also a second supply line 300b for supplying the second precursor B from a second precursor source 330b to the at least one second precursor nozzle 3b and connected to the second precursor nozzle 3b such that the second supply line 330b is in a fluid communication with the supply channel 30 of the second precursor nozzle 3b. The apparatus further comprises a first discharge line 400a for discharging the first precursor A and generating a discharge flow from the output face 2 and a second discharge line 400b for discharging the second precursor B and generating a discharge flow from the output face 2. The first discharge line 400a is connected to the first discharge nozzle 4a and is in a fluid communication with the discharge channel 40 of the first discharge nozzle 4a and the second discharge line 400b is connected to the second discharge nozzle 4b and is in a fluid communication with the discharge channel 40 of the second discharge nozzle 4b. The first discharge line 400a is connected to the first supply line 300a for circulating the first precursor A in the nozzle head 1 by returning at least part of the discharge flow from the output face 2 of the nozzle head 1 via the discharge channel 40 of the first discharge nozzle 4a to the first supply channel 30a of the first precursor nozzle 3a and the second discharge line 400b is connected to the second supply line 300b for circulating the second precursor B in the nozzle head 1 by returning at least part of the discharge flow from the output face 2 of the nozzle head 1 via the discharge channel 40 of the second discharge nozzle 4b to the supply channel 30 of the second precursor nozzle 3b. Both discharge lines 400a, 400b may comprise devices that are explained in connection with previous figures.

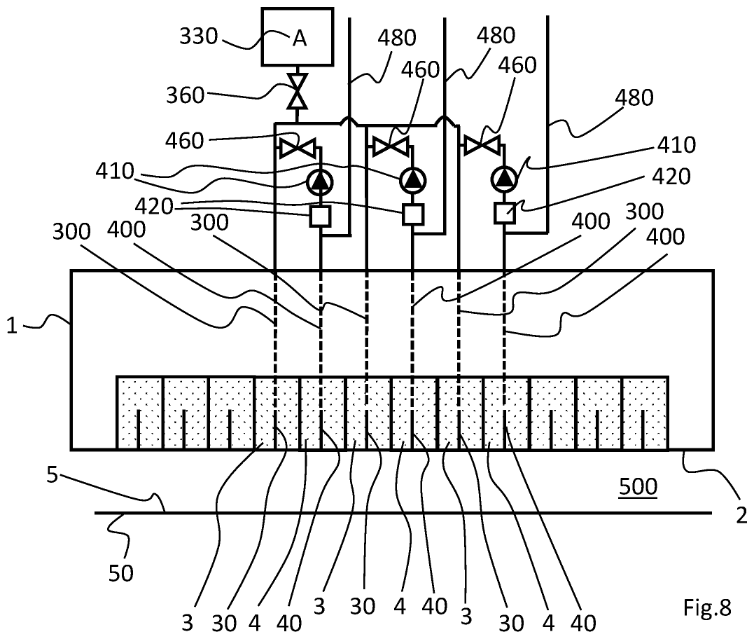

FIG. 8 shows an embodiment of the invention in which the apparatus comprises a nozzle head 1 having an output face 2 via which the at least one precursor is supplied towards the surface 5 of the substrate 50. A reaction space is 500 provided between the surface 5 of the substrate 50 and the output face 2 of the nozzle head 1. The nozzle head 1 comprises in this embodiment of the invention multiple precursor nozzles 3 provided on the output face 2 of the nozzle head 1 and comprising a supply channel 30 for supplying precursor towards the surface 5 of the substrate 50 via the output face 2. The nozzle head 1 further comprises multiple discharge nozzles 4 provided on the output face 2 of the nozzle head 1 and comprising a discharge channel 40 for discharging precursor from the output face 2. The nozzle head further comprises multiple supply lines 300 for supplying precursor from a precursor source 330 to the precursor nozzles 3 and multiple discharge lines 400 for discharging precursor and generating a discharge flow from the output face 2, the discharge lines 400 are connected to the discharge nozzles 4. In this embodiment of the invention a single precursor source 330 is supplying precursor to multiple precursor nozzles 3 through multiple supply lines 300. The discharge lines 400 are connected to the supply lines 300 for circulating precursor in the nozzle head 1 by returning at least part of the discharge flow from the output face 2 of the nozzle head 1 via the discharge channels 40 of the discharge nozzle 4 to the supply channels 30 of the precursor nozzle 3.

In the embodiment of the invention shown in FIG. 8 the precursor source 330 supplies precursor A to multiple precursor nozzles 3 and the supply of the precursor A is regulated by a second mass flow controller 360 provided between the precursor source 330 and the coupling between the supply lines 300 and the discharge lines 400. The second mass flow controller 360 is in other words regulating the precursor A supplied from the precursor source 330 to all the supply lines 300. The discharge lines 400 are connected to the supply lines 300 for circulating precursor in the nozzle head 1 by returning at least part of the discharge flow from the output face 2 of the nozzle head 1 via the discharge channels 40 of the discharge nozzles 4 to the supply channels 30 of the precursor nozzles 3. In this embodiment of the invention each supply line 300 has a connection to a discharge line 400 such that there are multiple precursor circulations in the nozzle head 1 although there is a single precursor source 330 supplying precursor A for the multiple precursor circulations. The discharge lines 400 preferably comprise filters 420, pumps 410, first mass flow controllers 460 and exhaust ventilations 480 as already explained in connection with previous figures.

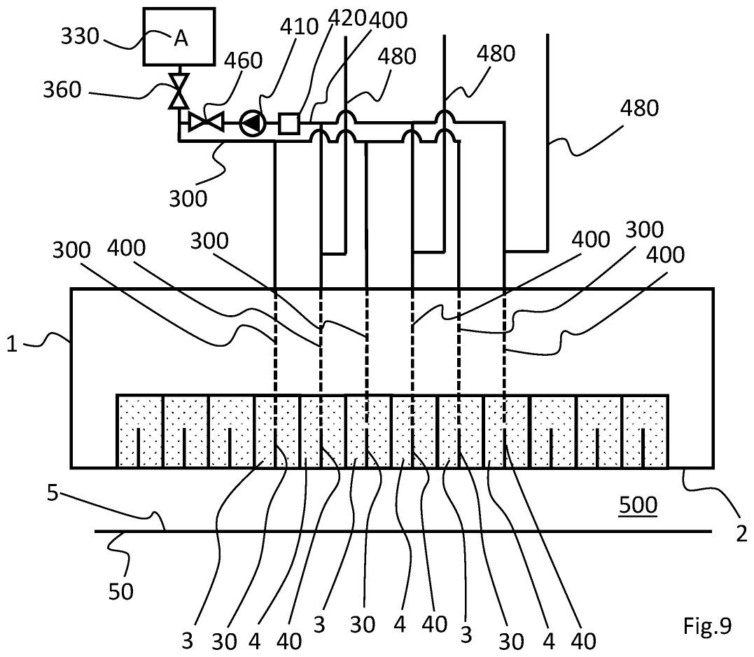

In another embodiment of the invention shown in FIG. 9 the precursor source 330 supplies precursor A to multiple precursor nozzles 3 and the supply of the precursor A is regulated by a second mass flow controller 360 provided between the precursor source 330 and the coupling between the supply lines 300 and the discharge lines 400. The second mass flow controller 360 is in other words regulating the precursor A supplied from the precursor source 330 to all the supply lines 300. The discharge lines 400 are connected to the supply lines 300 for circulating precursor in the nozzle head 1 by returning at least part of the discharge flow from the output face 2 of the nozzle head 1 via the discharge channels 40 of the discharge nozzles 4 to the supply channels 30 of the precursor nozzles 3. In this embodiment of the invention the discharge lines 400 coming from different discharge nozzles 4 are connected before the discharge line 400 is provided with the filter 420, the pump 410 and the first mass flow controller 460. In other words, the discharge lines 400 comprise a common filter 420, a common pump 410 and a common first mass flow controller 460. Further the precursor source 330 supplying precursor A is common for all the precursor nozzles 3.

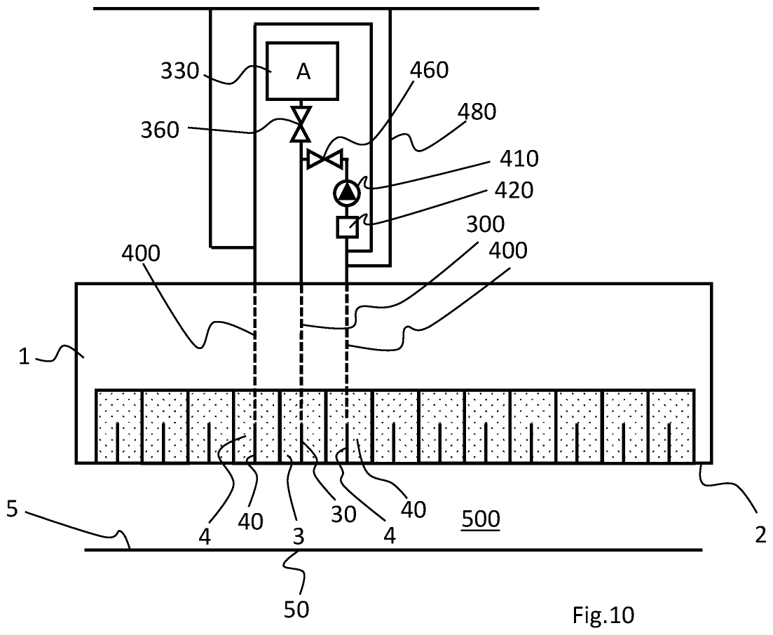

In an embodiment shown in FIG. 10 the nozzle head 1 comprises at least two discharge nozzles 4 and at least one precursor nozzle 3 such that one precursor nozzle 3 is provided between two discharge nozzles 4. The apparatus then comprises at least two discharge lines 400 for discharging precursor and generating a discharge flow from the output face 2 connected to the discharge nozzles 4 which are provided on opposite sides of the precursor nozzle 3 and which are in a fluid communication with the discharge channels 40 of the discharge nozzles 4. The discharge lines 400 are connected to the supply line 300 for circulating precursor in the nozzle head 1 by returning at least part of the discharge flow from the output face 2 of the nozzle head 1 via the discharge channels 40 of the discharge nozzles 4 to the supply channel 30 of the precursor nozzle 3. In other words, there are two loops for circulating the same precursor such that there are two discharge lines 400 to return at least part of the discharge flow to the supply line 300. The two discharge lines 400 are connected together before the discharged precursor is entering to a common filter 420 provided in the common discharge line 400, to a common pump 410 provided in the common discharge line 400 and to a common first mass flow controller 460 provided in the common discharge line 400.

The invention has been described above with reference to the examples shown in the figures. However, the invention is in no way restricted to the above examples but may vary within the scope of the claims.

1.-14. (canceled)

15. An apparatus for subjecting a surface of a substrate to alternate surface reactions of at least two precursors according to principles of atomic layer deposition, the apparatus comprising:
a nozzle head having an output face via which the at least one precursor is supplied towards the surface of the substrate, said nozzle head comprising:
at least one precursor nozzle provided on the output face of the nozzle head and comprising a supply channel for supplying precursor towards the surface of the substrate via the output face; and
at least one discharge nozzle provided on the output face of the nozzle head and comprising a discharge channel for discharging precursor from the output face;
a supply line for supplying precursor from a precursor source to the at least one precursor nozzle, said supply line being connected to the precursor nozzle and being in a fluid communication with the supply channel of the precursor nozzle, the supply line extending from the precursor source to the precursor channel in the precursor nozzle; and
a discharge line for discharging precursor and generating a discharge flow from the output face, said discharge line being connected to the discharge nozzle and being in a fluid communication with the discharge channel of the discharge nozzle;
wherein the discharge line extending from the discharge nozzle to the supply line such that the discharge line is connected to the supply line for circulating precursor in the nozzle head by returning at least part of the discharge flow from the output face of the nozzle head via the discharge channel of the discharge nozzle to the supply channel of the precursor nozzle.

16. The apparatus according to claim 15, wherein the nozzle head comprises at least two precursor nozzles provided on the output face of the nozzle head such that at least one first precursor nozzle is arranged to supply a first precursor (A) and at least one second precursor nozzle is arranged to supply a second precursor (B), and
the apparatus comprises:
a first supply line (300a) for supplying the first precursor (A) from a first precursor source to the at least one first precursor nozzle, said first supply line being connected to the first precursor nozzle and being in a fluid communication with the supply channel of the first precursor nozzle;
a second supply line for supplying the second precursor (B) from a second precursor source to the at least one second precursor nozzle, said second supply line being connected to the second precursor nozzle and being in a fluid communication with the supply channel of the second precursor nozzle;
a first discharge line for discharging the first precursor (A) and generating a discharge flow from the output face, said first discharge line being connected to the first discharge nozzle and being in a fluid communication with the discharge channel of the first discharge nozzle; and
a second discharge line for discharging the second precursor (B) and generating a discharge flow from the output face, said second discharge line being connected to the second discharge nozzle and being in a fluid communication with the discharge channel of the second discharge nozzle;
the first discharge line is connected to the first supply line for circulating the first precursor (A) in the nozzle head by returning at least part of the discharge flow from the output face of the nozzle head via the discharge channel of the first discharge nozzle to the first supply channel of the first precursor nozzle, and
the second discharge line is connected to the second supply line for circulating the second precursor (B) in the nozzle head by returning at least part of the discharge flow from the output face of the nozzle head via the discharge channel of the second discharge nozzle to the supply channel of the second precursor nozzle.

17. The apparatus according to claim 15, wherein the nozzle head comprises at least two discharge nozzles and at least one precursor nozzle such that one precursor nozzle is provided between two discharge nozzles; and the apparatus comprises:
at least two discharge lines for discharging precursor and generating a discharge flow from the output face, said at least two discharge lines being connected to the discharge nozzles provided on opposite sides of the precursor nozzle and being in a fluid communication with the discharge channels of the discharge nozzles;
said discharge lines are connected to the supply line for circulating precursor in the nozzle head by returning at least part of the discharge flow from the output face of the nozzle head via the discharge channels of the discharge nozzles to the supply channel of the precursor nozzle.

18. The apparatus according to claim 15, wherein the discharge line comprises at least one of the following:
a pump for circulating a discharge flow (DF) and/or a circulation flow (CF);
a first filter for filtering the discharge flow (DF) or the circulation flow (CF);
a first mass flow controller for regulating the circulation flow (CF) to the supply line;
a coupling with an exhaust ventilation for connecting the discharge line to the exhaust ventilation.

19. The apparatus according to claim 15, wherein the discharge line comprises:
a first mass flow controller and a filter provided upstream side of the mass flow controller; or
a first mass flow controller and a pump provided upstream side of the mass flow controller; or
a first mass flow controller, a pump and a first filter, said pump is provided upstream side of the mass flow controller and said first filter is provided upstream side of the pump; or
a first mass flow controller, a pump, a first filter and a second filter, said second filter is provided upstream side of the mass flow controller, said pump is provided upstream side of the second filter and said first filter is provided upstream side of the pump.

20. The apparatus according to claim 15, wherein the supply line comprises a second mass flow controller for regulating precursor flow (PF) from the precursor source, said second mass flow controller is provided in the supply line between the precursor source and the connection of the discharge line to the supply line.

21. The apparatus according to claim 15, wherein the discharge line is connected to the supply line with a first coupling and to an exhaust ventilation with a second coupling, and the first mass flow controller is provided in the discharge line between the first coupling and the second coupling.

22. A method for circulating precursor in an apparatus for subjecting a surface of a substrate to alternate surface reactions of at least two precursors according to the principles of atomic layer deposition, the apparatus comprising a nozzle head having an output face and at least one precursor nozzle and at least one discharge nozzle provided on the output face, wherein the apparatus comprises a supply line extending from a precursor source to a precursor channel in the precursor nozzle and a discharge line extending from the discharge nozzle to the supply line, and
the method comprises the steps of:
supplying precursor from the precursor nozzle via the output face toward the surface of the substrate as a precursor flow (PF);
discharging precursor from the output face through the discharge nozzle as a discharge flow (DF); and
returning at least part of the discharge flow from the discharge nozzle to the precursor nozzle as a circulation flow (CF) by circulating the at least part of the discharge flow (DF) through the discharge line to the supply line as the circulation flow (CF).

23. The method according to claim 22, wherein the method further comprises the step of:
dividing the discharge flow to the circulation flow (CF) and an exhaust flow (EF).

24. The method according to claim 22, wherein the apparatus further comprises a first mass flow controller provided in the discharge line, the method further comprises the step of:
regulating the circulation flow (CF) to the supply line by the first mass flow controller; or
regulating the ratio of the circulation flow (CF) divided from the discharge flow to the supply line by the first mass flow controller.

25. The method according to claim 22, wherein the apparatus further comprises a first filter provided in the discharge line, the method further comprises the step of:
filtering the circulation flow (CF) upstream of the supply line.

26. The method according to claim 22, wherein the apparatus further comprises a second mass flow controller provided in the supply line, the method further comprises the step of:
regulating the precursor flow (PF) supplied from the precursor source with the second mass flow controller.

27. The method according to claim 22, wherein the nozzle head comprises at least two precursor nozzles and at least two discharge nozzles provided on the output face, the method comprises the steps of:
supplying a first precursor (A) from a first precursor nozzle via the output face toward the surface of the substrate as a first precursor flow (PF);
supplying a second precursor (B) from a second precursor nozzle via the output face toward the surface of the substrate as a second precursor flow (PF);
discharging the first precursor (A) from the output face through a first discharge nozzle as a first discharge flow (DF);
discharging the second precursor (B) from the output face through a second discharge nozzle as a second discharge flow (DF);
returning at least part of the first discharge flow through the first discharge nozzle to the first precursor nozzle as a first circulation flow (CF); and
returning at least part of the second discharge flow (DF) through the second discharge nozzle to the second precursor nozzle as a second circulation flow (CF).

28. The method according to claim 22 further comprising:
providing the nozzle head with features which comprise:
at least one precursor nozzle provided on the output face of the nozzle head and comprising a supply channel for supplying precursor towards the surface of the substrate via the output face;
at least one discharge nozzle provided on the output face of the nozzle head and comprising a discharge channel for discharging precursor from the output face; and
a discharge line for discharging precursor and generating a discharge flow from the output face, said discharge line being connected to the discharge nozzle and being in a fluid communication with the discharge channel of the discharge nozzle;
wherein the discharge line extending from the discharge nozzle to the supply line such that the discharge line is connected to the supply line for circulating precursor in the nozzle head by returning at least part of the discharge flow from the output face of the nozzle head via the discharge channel of the discharge nozzle to the supply channel of the precursor nozzle.
